(19) United States
(12) Patent Application Publication
(10) Pub. No.: US 2002/0039022 A1
(43) Pub. Date: Apr. 4, 2002

(54) Calibration device for semiconductor testing apparatus, calibration method and semiconductor testing apparatus

(75) Inventor: Keiji Yamamoto, Tokyo (JP)

Correspondence Address: OLIFF & BERRIDGE, PLC, P.O. BOX 19928, ALEXANDRIA, VA, 22320, US

(73) Assignee: Ando Electric Co., Ltd., Tokyo (JP)

(21) Appl. No.: 09/948,686

(22) Filed: Sep. 10, 2001

(30) Foreign Application Priority Data
Sep. 29, 2000 (JP) 2000-299789

(51) Int. Cl. G01R 1/00

(52) U.S. Cl. 324/158.1

(57) ABSTRACT

A calibration device for a semiconductor testing apparatus, comprises: an inspection section comprising an inspector for detecting an inspection reference portion provided on a calibration board mounted on the semiconductor testing apparatus; a movement section for moving the inspector to an optional position of an upper surface of the calibration board, and for moving the inspector vertically in the optional position of the upper surface of the calibration board; and a control unit for setting an inspection line passing through the inspection reference portion, for controlling the inspector so as to move the inspector along the set inspection line to detect the inspection reference portion, for determining a center coordinate of the inspection reference portion in accordance with a middle coordinate of a range that the inspection reference portion is detected along the set inspection line, and for compensating a coordinate of a measurement position of the calibration board in accordance with the determined center coordinate in order to precisely contact a probe with the measurement position.

### BACKGROUND OF THE INVENTION

1. Field of the Invention

The present invention relates to a calibration device for a semiconductor testing apparatus, which is used for the calibration of the semiconductor testing apparatus.

2. Description of Related Art

According to an earlier development, in general, there is a variation in the characteristic of semiconductor devices, such as ICs (Integrated Circuit), product by product. In order to extract a product having a characteristic departing from a regulated standard, it is known that a semiconductor testing apparatus for evaluating a semiconductor device is used. The semiconductor testing apparatus comprises a test head for attaching the semiconductor device so as to evaluate the semiconductor device.

The evaluation of the semiconductor device is carried out as follows. That is, a DUT (device under test) having a plurality of IC sockets for setting a plurality of semiconductor devices is mounted on the test head. A plurality of semiconductor devices are evaluated by the semiconductor testing apparatus all at once. A predetermined signal is inputted into the semiconductor devices set to the IC sockets. The semiconductor testing apparatus executes the semiconductor devices to carry out a predetermined process in accordance with the inputted signal. It is judged whether the semiconductor device satisfies the regulated standard by comparing the result of the process with a standard value which is previously stored in the semiconductor testing apparatus.

The standard of the semiconductor device or the condition of the measurement (evaluation) varies with the type of the semiconductor device. Therefore, when the type of the semiconductor is changed, the calibration of the semiconductor testing apparatus is carried out before the test of the semiconductor device. The semiconductor testing apparatus is calibrated in order to precisely judge whether the semiconductor device is good.

For example, the calibration of the semiconductor testing apparatus is adjusted by using a special calibration board as follows. That is, first of all, instead of a DUT unit, the calibration board is mounted on a test head. The calibration board comprises a plurality of printed boards on which a predetermined circuit for the calibration of the semiconductor testing apparatus is formed. Next, in order to carry out the measurement, a probe to be connected with an output device, such as an oscilloscope, is in contact with a predetermined measurement position provided on the printed board of the calibration board (for example, a gold-plated pad for the measurement, which is provided on the printed board). A calibration device previously grasps a coordinate system (for example, XY coordinate system) on which a plurality of gold-plated pads for the measurement are provided. The calibration device controls the probe so as to be in contact with the gold-plated pad for the measurement in accordance with the grasped coordinate system. While an output signal obtained through the probe is monitored by the oscilloscope or the likes the semiconductor testing apparatus is adjusted so as to adapt it to the standard of the semiconductor device to be measured.

As described above, in the calibration of the semiconductor testing apparatus, it is required to precisely introduce the probe to the position of the gold-plated pad provided on the printed board of the calibration board. However, as the semiconductor testing apparatus becomes small in recent years, a plurality of gold-plated pads which are provided on the measurement positions tend to be finely provided (for example, a circular form having a diameter of about 0.5 mm). When the probe is precisely introduced, the following difficulty is caused.

That is, during the calibration, the calibration board or the calibration device is attached to the semiconductor testing apparatus. Then, there is some possibility to cause an error by mounting the calibration board on the test head, or an error by mounting the calibration device on the semiconductor testing apparatus. Therefore, there is some possibility that the probe is not precisely introduced to the position of the gold-plated pad when the probe is moved in accordance with the previously grasped coordinate.

For example, when an X1-Y1 coordinate system which is determined on the upper surface of the calibration board, is shifted with respect to an X0-Y0 coordinate system which the calibration device has for the control of the probe, by deteriorating the perpendicularity of the X1-Y1 coordinate system, the probe is shifted with respect to an actual position of the gold-plated pad for the measurement in proportion to the movement of the probe. Further, the verticality between the direction in which the probe of the calibration device is moved upwardly and downwardly, and the upper surface of the calibration board, is not necessarily secured. Therefore, there is some possibility that the probe is shifted slightly.

### SUMMARY OF THE INVENTION

In order to solve the above-described problems, an object of the present invention is to compensate the position of the probe so as to introduce it to the gold-plated pad for the measurement, which is the measurement point of the calibration, in the semiconductor testing apparatus.

That is, in accordance with the first aspect of the present invention, a calibration device for a semiconductor testing apparatus, comprises:

an inspection section comprising an inspector for detecting an inspection reference portion provided on a calibration board mounted on the semiconductor testing apparatus;

a movement section for moving the inspector to an optional position of an upper surface of the calibration board, and for moving the inspector vertically in the optional position of the upper surface of the calibration board; and

a control unit for setting an inspection line passing through the inspection reference portion, for controlling the inspector so as to move the inspector along the set inspection line to detect the inspection reference portion, for determining a center coordinate of the inspection reference portion in accordance with a middle coordinate of a range that the inspection reference portion is detected along the set inspection line, and for compensating a coordinate of a measurement position of the calibration board in accordance with the determined center coordinate in order to precisely contact the inspector with the measurement position.

The probe is a measurement terminal for outputting a signal for calibrating the semiconductor testing apparatus, to an output device, for example, an oscilloscope or the like.

According to the first aspect of the present invention, by the movement section, the inspector is moved to an optional position of the upper surface of the calibration board mounted on the semiconductor testing apparatus, and is moved vertically in the optional position of the upper surface of the calibration board. Therefore, the inspector is moved along the inspection line set by the control unit so as to pass through the inspection reference portion and is controlled by the control unit so as to move the inspector to detect the inspection reference portion.

The range of detecting the inspection reference portion along the inspection line is grasped by the control unit. Further, the center coordinate of the inspection reference portion is determined by the control unit in accordance with the middle coordinate of the range of detecting the inspection reference portion. The center coordinate determined as above described is compared with a center coordinate of the inspection reference portion, which is previously set by the calibration device, in order to grasp an error of the optional position coordinate of the upper surface of the calibration board. The coordinate of the measurement position of the calibration board is compensated by the control unit in accordance with the grasped error.

Therefore, the coordinate of the measurement position of the calibration board is precisely grasped. The probe is precisely introduced to the measurement position by the control unit. The predetermined calibration is carried out.

The concrete structure of the inspection section is not limited. Various structures can be applied if a signal for detecting the inspection reference portion can be outputted. For example, a structure that each type of sensor, such as an optical sensor, a magnetic sensor or the like, is used, a structure that a shape (for example, a convex portion, a concave portion, an opening portion or the like) of the inspection reference portion is grasped, or a structure that each type of probe for detecting a characteristic value, such as a current value, a magnetic force or the like, is used, maybe applied. Preferably, the shape of the inspection reference portion is one which does not have a directional property to the optically set inspection line, for example, an approximate circle.

Preferably, the number of the provided inspection reference portions is two or more in order to secure the accuracy of the calibration. More preferably, the number of the inspection reference portions is three or more.

The inspector may be controlled to move the inspector to each position which is arranged at predetermined intervals along the inspection line.

The inspection reference portion is detected by the control unit in each position which is arranged at predetermined intervals along the inspection line. As a result, it is possible to easily grasp the inspection reference portion along the inspection line.

The predetermined interval for controlling the inspector so as to move it, is preferably short as compared with the size of the inspection reference portion so that there are enough positions in which the inspection reference portion is detected, to precisely grasp the center coordinate of the inspection reference portion.

The control unit may set a plurality of inspection lines to the inspection reference portion.

Because the a plurality of inspection lines are set to one inspection reference portion by the control unit, the center coordinate of the inspection reference portion is grasped more precisely. Therefore, an optional position coordinate of the upper surface of the calibration board can be precisely compensated.

The inspection reference portion may have an electric conductivity; and the control unit may detect the inspection reference portion by detecting an electric continuity between the inspector and the inspection reference portion.

Because the electric continuity between the inspection reference portion having an electric conductivity and the inspection section is detected by the control unit, the inspection reference portion can be suitably detected.

The inspector may be the probe for detecting a signal to calibrate the semiconductor testing apparatus; and the movement section may be a calibration robot for contacting the probe with the measurement position of the calibration board when the semiconductor testing apparatus is calibrated.

The coordinate of the measurement position for the calibration is compensated by using an ordinary structure without providing a special structure for compensating the coordinate of the measurement position for the calibration. Therefore, the calibration device can have an simple structure and the manufacturing cost thereof can be reduced.

The calibration board may comprise a printed board; and the inspection reference portion may be a gold-plated pad which is previously provided on the printed board.

The electric insulation can be secured around the gold-plated pad provided on the printed board. Therefore, when the gold-plated pad is detected along the inspection line passing through the gold-plated pad which is the inspection reference portion, it is clear whether there is an electric continuity within or out of the gold-plated pad. The gold-plated pad can be suitably detected. Further, by using a known equipment for producing a printed board, a desired gold-plated pad can be easily provided.

The inspection reference portion may be an opening portion formed on the upper surface of the calibration board mounted on the semiconductor testing apparatus; the inspection section may comprise a vertical displacement detecting unit for detecting a displacement of an end portion of the inspector in upper and lower direction; and the control unit may set the inspection line passing through the opening portion, may control the inspector so as to move the inspector along the set inspection line, and may detect the opening portion in accordance with the detected displacement of the end portion of the inspector in the upper and lower direction.

The inspection section comprises the vertical displacement detecting unit for detecting the displacement of the end portion of the inspector in the upper and lower direction. When the inspection reference portion is detected by the control unit along the inspection line, the vertical displacement detecting unit of the inspection section outputs a signal relating to the displacement of the end portion of the inspector in the upper and lower direction. When the inspector is moved by the movement section along the inspection line, in the opening portion, the end portion of the inspector is inserted below the upper surface of the calibration board.

Therefore, by monitoring the displacement of the end portion of the inspection section in the vertical direction with the vertical displacement detecting unit, the opening portion can be suitably detected.

In accordance with the second aspect of the present invention, a calibration method for calibrating a semiconductor testing apparatus, comprises:

setting an inspection line passing through an inspection reference portion provided on a calibration board mounted on the semiconductor testing apparatus;

moving an inspector for detecting the inspection reference portion along the set inspection line in order to detect the inspection reference portion;

determining a center coordinate of the inspection reference portion in accordance with a middle coordinate of a range that the inspection reference portion is detected along the set inspection line; and

compensating a coordinate of a measurement position of the calibration board in accordance with the determined center coordinate in order to precisely contact a probe with the measurement position.

The inspector may be moved to each position arranged at predetermined intervals along the inspection line.

A plurality of inspection lines may be set to the inspection reference portion.

In accordance with the third aspect of the present invention, a semiconductor testing apparatus comprises:

a calibration device for the semiconductor testing apparatus, the calibration device comprising:

an inspection section comprising an inspector for detecting an inspection reference portion provided on a calibration board mounted on the semiconductor testing apparatus;

a movement section for moving the inspector to an optional position of an upper surface of the calibration board, and for moving the inspector vertically in the optional position of the upper surface of the calibration board; and

a control unit for setting an inspection line passing through the inspection reference portion, for controlling the inspector so as to move the inspector along the set inspection line to detect the inspection reference portion, for determining a center coordinate of the inspection reference portion in accordance with a middle coordinate of a range that the inspection reference portion is detected along the set inspection line, and for compensating a coordinate of a measurement position of the calibration board in accordance with the determined center coordinate in order to precisely contact a probe with the measurement position.

The inspector may be controlled to move the inspector to each position which is arranged at predetermined intervals along the inspection line.

The control unit may set a plurality of inspection lines to the inspection reference portion.

The inspection reference portion may have an electric conductivity; and the control unit may detect the inspection reference portion by detecting an electric continuity between the inspector and the inspection reference portion.

The inspector may be the probe for detecting a signal to calibrate the semiconductor testing apparatus; and the movement section may be a calibration robot for contacting the probe with the measurement position of the calibration board when the semiconductor testing apparatus is calibrated.

The calibration board may comprise a printed board; and the inspection reference portion may be a gold-plated pad which is previously provided on the printed board.

The inspection reference portion may be an opening portion formed on the upper surface of the calibration board mounted on the semiconductor testing apparatus; the inspection section may comprise a vertical displacement detecting unit for detecting a displacement of an end portion of the inspector in upper and lower direction; and the control unit may set the inspection line passing through the opening portion, may control the inspector so as to move the inspector along the set inspection line, and may detect the opening portion in accordance with the detected displacement of the end portion of the inspector in the upper and lower direction.

### BRIEF DESCRIPTION OF THE DRAWINGS

The present invention will become more fully understood from the detailed description given hereinbelow and the accompanying drawings which are given by way of illustration only, and thus are not intended as a definition of the limits of the present invention, and wherein;

FIG. 1 is a view showing a construction of a semiconductor testing apparatus comprising a calibration device according to the first embodiment to which the present invention is applied;

FIG. 2 is a perspective view showing a principal construction of a calibration robot shown in FIG. 1;

FIG. 3A is a perspective view showing a construction of a calibration board shown in FIG. 1, and FIG. 3B is a perspective view showing a printed board;

FIG. 4 is a plan view showing a calibration board according to the first embodiment;

FIG. 5 is a block diagram showing a construction of a calibration device according to the first embodiment;

FIG. 6 is a view showing a state of grasping a center coordinate A of a gold-plated pad for a position index;

FIG. 7 is a flowchart showing a coordinate compensating process;

FIG. 8 is a flow chart showing a coordinate compensating process;

FIG. 9 is a plan view showing a calibration board according to the second embodiment; and

FIG. 10 is a block diagram showing a construction of a calibration device according to the second embodiment.

### PREFERRED EMBODIMENT OF THE INVENTION

First Embodiment

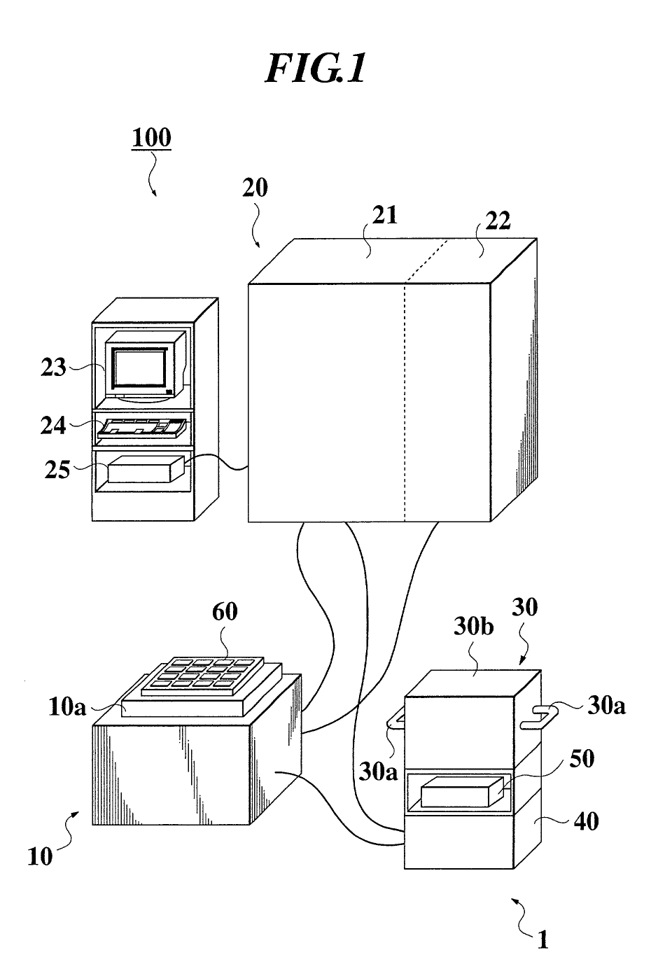

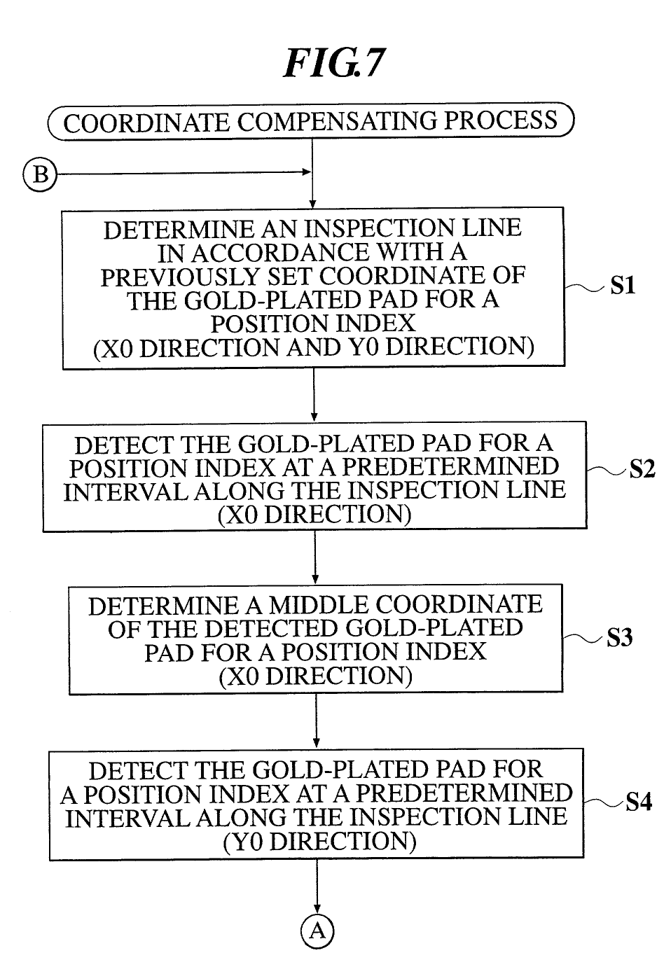

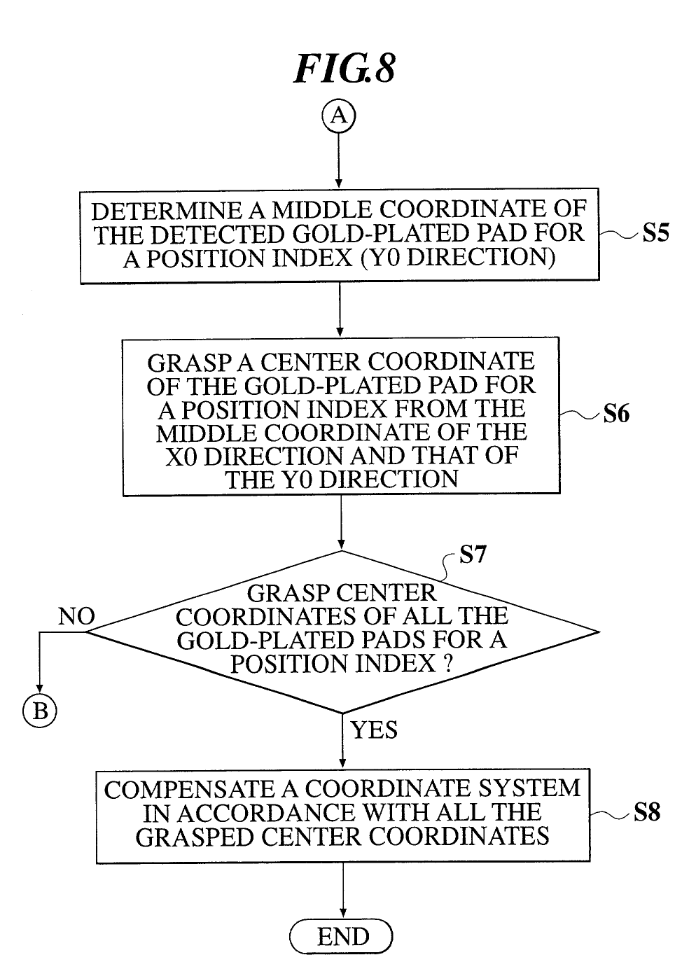

Hereinafter, the calibration device 1 for a semiconductor testing apparatus (hereinafter, simply referred to as calibration device 1) according to the first embodiment of the present invention will be explained in detail with reference to FIGS. 1 to 8. The calibration device 1 according to the first embodiment is provided in the semiconductor testing apparatus 100 for evaluating whether a semiconductor device has a characteristic within a regulated standard.

Before a semiconductor device is evaluated by the semiconductor testing apparatus 100, the calibration device 1 is used for the calibration that the semiconductor testing apparatus 100 is calibrated so as to meet the requirement or the standard of the semiconductor device. In the calibration, as shown in FIG. 1, a special calibration board 60 is mounted on the test head 10. The calibration board 60 comprises a plurality of gold-plated pads 62a for a measurement, which are provided on measurement positions in the calibration.

The calibration device 1 compensates a coordinate system which the calibration device 1 previously memorizes, by the coordinate compensating process which will be described below. The calibration device 1 precisely grasps the coordinate of the gold-plated pad 62a for the measurement. Then, in accordance with the compensated coordinate, an inspection probe 34a of the probe 34 is precisely introduced to the gold-plated pad 62a for the measurement in order to output a signal for calibrating the semiconductor testing apparatus 100.

First, the construction of the semiconductor testing apparatus 100 comprising the calibration device 1 will be explained below.

As shown in FIG. 1, the semiconductor testing apparatus 100 comprises the calibration device 1 according to the first embodiment, a test head 10, a body part 20 for controlling the evaluation of the semiconductor device, which is carried out by the semiconductor testing apparatus 100.

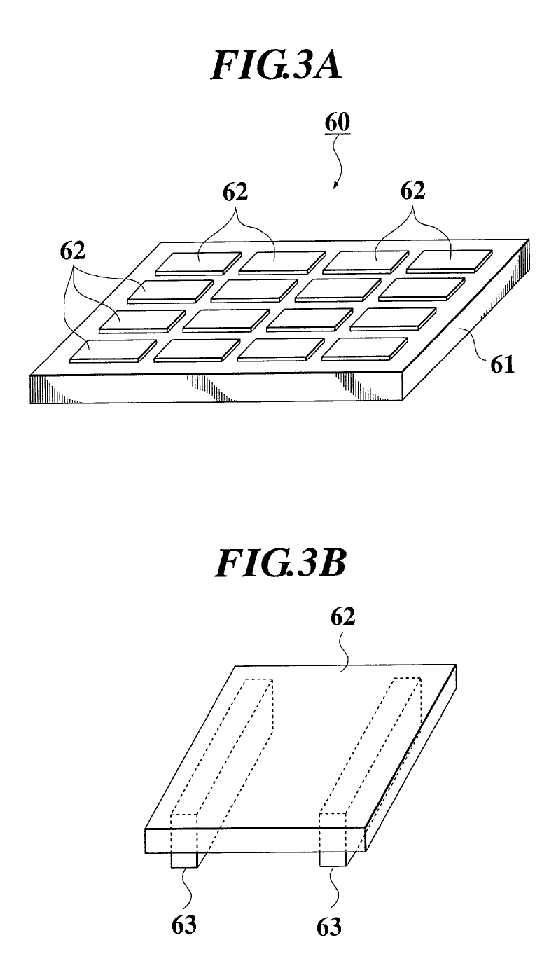

As shown in FIG. 1, a DUT interface 10a is unitedly provided on the upper portion of the test head 10. The calibration board 60 is attached to or detached from the upper surface of the DUT interface 10a via connectors 63 shown in FIG. 3B. An attachment portion (not shown in the figure) for inserting the connector 63 which the calibration board 60 has, is provided on the DUT interface 10a. The calibration board 60 mounted on the DUT interface 10a transmits one or more signals for the calibration, to the test head 10 via the connectors 63.

A DUT unit (not shown in the figure) mounted to evaluate the semiconductor device, is also mounted on the test head 10 via the connectors like the calibration board 60.

As shown in FIG. 1, the body part 20 comprises a body part container 21 containing a power supply and a printed board which are not shown in the figure, and a water cooling container 22 for cooling a printed board (not shown in the figure) which is provided in the test head 10. The body part 20 further comprises a display 23, for example, a CRT (Cathode Ray Tube) or an LCD (Liquid Crystal Display), an input device 24, for example, a keyboard, and a personal computer 25. The display 23 outputs the result of the evaluation of a semiconductor device or the like, to an operator. The operator inputs necessary data relating to the evaluation of a semiconductor device, into the body part 20 via the input device 24. Because the body part 20 is constructed as described above, the body part 20 controls the evaluation of a semiconductor device, which is carried out by the semiconductor testing apparatus 100.

Hereinafter, the structure of the calibration device 1 will be explained below.

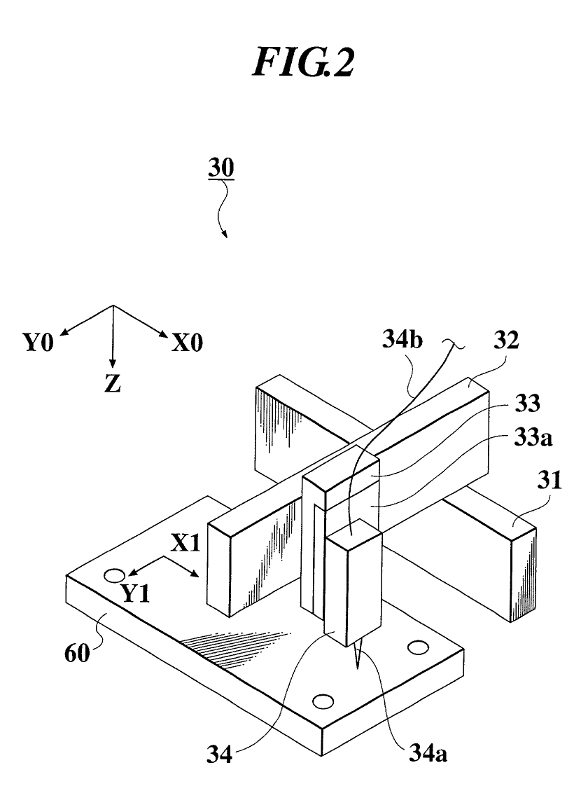

As shown in FIG. 1, the calibration device 1 mainly comprises a calibration robot 30 (shown in FIG. 2) for holding and moving a probe 34, a control unit 40 for controlling the calibration by using the probe 34. The calibration robot 30 is mounted on the semiconductor testing apparatus 100 during the calibration. The probe 34 is connected with the oscilloscope 50 via a wire 34b shown in FIG. 2. One or more signals are outputted from the probe 34 to the oscilloscope 50. A device to which the signals are outputted from the probe 34 is not limited to the oscilloscope 50. Other devices may be applied.

A coordinate system which is used for the following explanation, is determined as follows.

That is, as shown in FIG. 2, the X0-Y0 coordinate system is a coordinate system which is previously set by the calibration device 1. The X1-Y1 coordinate system is a coordinate system which is determined on the upper surface of the calibration board 60 mounted on the DUT interface 10a. Because of a setting error caused by mounting the calibration robot 30 and the calibration board 60, an optional position which is on the upper surface of the calibration board 60, generally varies between the X0-Y0 coordinate system and the X1-Y1 coordinate system. Further, the X2-Y2 coordinate system is a coordinate system which is set by the calibration device 1 after the coordinate system is compensated in accordance with the coordinate compensating process.

As shown in FIG. 1, the calibration robot 30 comprises two handles 30a provided on both sides of a cover 30b. The operator holds two handles 30a to mount the calibration robot 30 on the test head 10 together with the cover 30b. In the cover 30b of the calibration robot 30, the following members are provided so as to hold the probe 34 for outputting the signals for the calibration and to move it to a predetermined position.

That is, as shown in FIG. 2, a guide shaft 31, a movable shaft 32 which is perpendicular to the guide shaft 31 and is movable so as to slide in a direction along the upper surface of the guide shaft 31, are provided. A slide member 33 which is movable so as to slide in a direction along the side surface of the movable shaft 32, is provided. Further, a support member 33a for supporting the probe 34, is provided on the slide member 33 so as to be movable upwardly and downwardly in a vertical direction.

The control unit 40 determines the X0-Y0 coordinate system when the calibration robot 30 is controlled. That is, as shown in FIG. 2, a direction that the guide shaft 31 extends is determined as an X0 axis. A direction that the movable shaft 32 extends is determined as a Y0 axis. The movement of the probe 34 supported by the support member 33a of the calibration robot 30 is controlled in accordance with the X0-Y0 coordinate system determined by the control unit 40.

The probe 34 comprises an inspection probe 34a which can protrude from and retract into the lower surface of the probe 34 in a state that the probe 34 is supported by the support member 33a. In the calibration, an end portion of the inspection probe 34a of the probe 34 is in contact with the gold-plated pad 62a for the measurement in order to carry out the predetermined calibration. The inspection probe 34a of the probe 34 is moved upwardly and downwardly by moving the support member 33a downwardly in the Z-direction. In the probe 34 for holding the inspection probe 34a, a spring (not shown in the figure) for biasing the inspection probe 34a in a state of protruding it from the lower surface of the probe 34, is provided. When the support member 33a is moved more downwardly in a state that the inspection probe 34a is in contact with the upper surface of the calibration board 60, the inspection probe 34a retracts into the probe 34 by a spring (not shown in the figure) provided in the probe 34. Therefore, an end portion of the inspection probe 34a firmly contacts with the upper surface of the calibration board 60. Further, because a pressing force for contacting the inspection probe 34a with the calibration board 60, is absorbed, it is prevented that the upper surface of the calibration board 60 is damaged.

As described above, the calibration robot 30 holds the probe 34 and moves the probe 34 to a predetermined position under the control of the control unit 40 in accordance with the X0-Y0 coordinate system (or the compensated X2-Y2 coordinate system). That is, the calibration device 1 moves the probe 34 to an optional position on the upper surface of the calibration board 60 and moves the probe 34 upwardly and downwardly in the optional position on the upper surface of the calibration board 60.

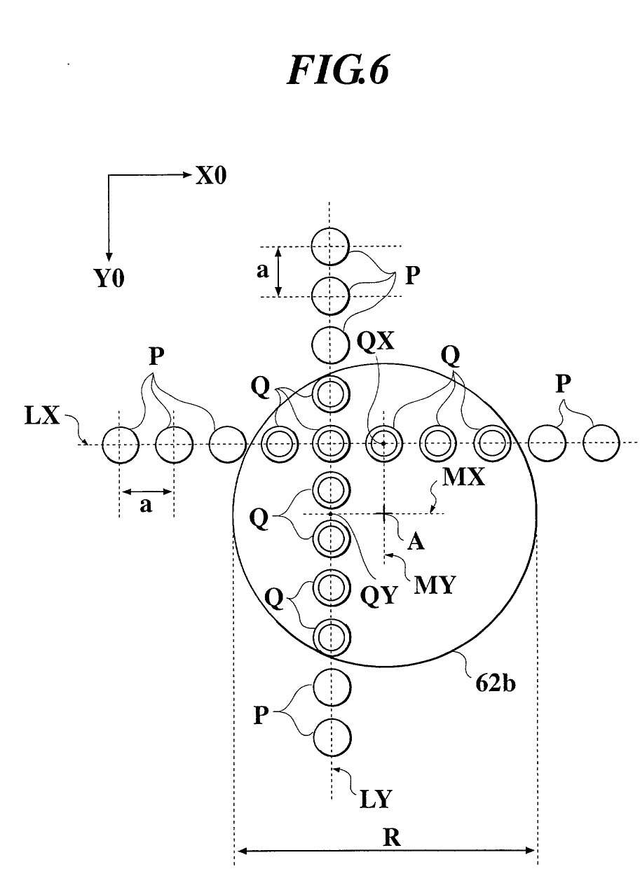

In the first embodiment, a center coordinate A (shown in FIG. 6) of the gold-plated pad 62b for a position index is precisely grasped by the inspection probe 34a (inspector) of the probe 34. As a result, the X0-Y0 coordinate system which is previously set by the calibration robot 30, is compensated. That is, in the first embodiment, the inspection section comprises the probe 34 and the inspection probe 34a. The calibration robot 30 is the movement section.

Although the coordinate is not set to a Z-direction in the first embodiment, the calibration robot 30 is controlled so as to move the inspection probe 34a of the probe 34 enough to contact the inspection probe 34a with the upper surface of the calibration board 60.

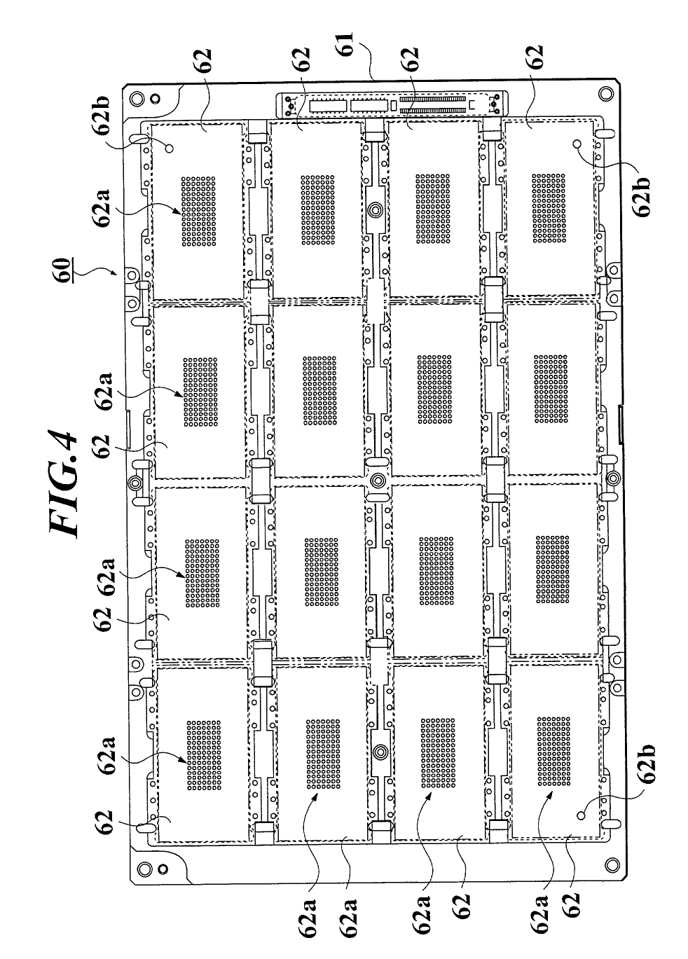

As shown in FIGS. 3A and 4, the calibration board 60 comprises a plurality of printed boards 62 on the upper surface of an aluminum base 61. As shown in FIG. 3B, the connectors 63 projecting from the lower surface of each printed board 62, are provided so as to penetrate the aluminum base 61. In the connectors 63, a plurality of wires which lead from the printed board 62 are collected. The connectors 63 projecting from each printed board 62 are inserted into an attachment portion (not shown in the figure) provided on the DUT interface 10a of the test head 10. Each printed board 62 corresponds to an IC socket (not shown in the figure) provided on the DUT unit which is replaced with the DUT interface 10a during the evaluation of a semiconductor device. In this embodiment, 16 (4 pieces ×4 pieces) printed boards 62 are provided so as to correspond the number of IC sockets provided on the DUT unit.

As shown in the plan view of FIG. 4, a large number of gold-plated pads for the measurement are provided on an approximate center portion of each printed board 62 in a predetermined arrangement. A gold-plated pad 62b for a position index (inspection reference portion) is provided one by one on three printed boards 62 selected from four printed boards 62 arranged at the corner. That is, in this embodiment, the gold-plated pads 62b for a position index are provided in three positions of the calibration board 60. The gold-plated pads 62b for a position index are used in the coordinate compensating process carried out before the calibration. By precisely grasping the center coordinate of the gold-plated pad 62b for a position index, the previously set X0-Y0 coordinate system is compensated. The gold-plated pad 62b for a position index is provided in an approximate circle.

By using a plurality of gold-plated pads 62b for a position index to compensate the coordinate system, the accuracy of the coordinate compensating process can be improved. Further, the gold-plated pad 62b for a position index is larger than the gold-plated pad 62a for the measurement. Therefore, the center coordinate of the gold-plated pad 62b for a position index is grasped more in detail. The accuracy of the coordinate compensating process can be improved more.

Further, the arrangement of three gold-plated pads 62b for a position index is considered so as to be sufficiently apart from each other within the extent that the calibration board 60 comprises a plurality of printed boards 62. That is, in the coordinate compensating process, the coordinate system can be compensated within the wide extent that the calibration board 60 comprises a plurality of printed boards 62. The accuracy of the coordinate compensating process can be improved more. Therefore, although the distance that the probe 34 is moved on the upper surface of the calibration board 60 is long to a certain degree, the error between the target position of the moved probe 34 and the actual position thereof is extremely reduced.

Because of the setting error caused by mounting the calibration robot 30 and the calibration board 60, there is some possibility that the perpendicularity between the direction that the probe 34 of the calibration robot 30 is moved upwardly and downwardly and the upper surface of the calibration board 60 is slightly shifted. When the perpendicularity is shifted, an optional coordinate of the upper surface of the calibration board 60, which is based on the X0-Y0 coordinate system, is shifted. In the first embodiment, because the probe 34 having the inspection probe 34a provided so as to protrude and retract, is sufficiently moved in the Z-direction, the shift of the perpendicularity is suitably absorbed by the X2-Y2 coordinate system determined in the coordinate compensating system.

Hereinafter, the construction of the control system of the calibration device 1 will be explained.

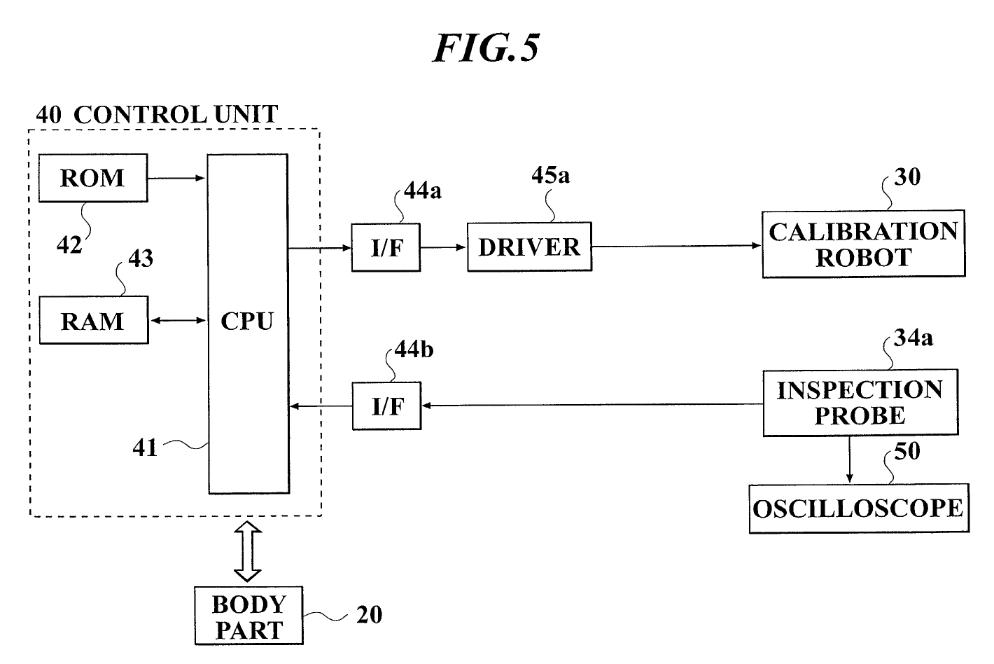

As shown in the block diagram shown in FIG. 5, the control unit 40 comprises a CPU (Central Processing Unit) 41 (control unit) for carrying out various processes for the calibration of the semiconductor testing apparatus 100 and for the coordinate compensating process. The control unit 40 comprises a ROM (Read Only Memory) 42 and a RAM (Random Access Memory) 43 which are connected with the CPU 41. In the ROM 42, one or more programs for carrying out various processes and data for being used with the programs are previously stored. Further, in the ROM 42, the coordinates of the gold-plated pads 62b for a position index and those of the gold-plated 62a for the measurement and the like are previously stored in accordance with the X0-Y0 coordinate system by using the arrangement (X1-Y1 coordinate system) of the upper surface of calibration board 60 mounted on the DUT interface 10a. In the RAM 43, data which is required when the CPU 41 carries out various processes, is stored. The coordinate based on the X0-Y0 coordinate system is compensated in accordance with the X2-Y2coordinate system compensated in the coordinate compensating process. The compensated coordinate is stored in the RAM 43. Further, the CPU 41 of the control unit 40 is connected with the body part 20 for controlling a series of evaluations of a semiconductor device, which is carried out by the semiconductor testing apparatus 100.

A driver 45a for driving the calibration robot 30 is connected with the CPU 41 via an I/F 44a. That is, the inspection probe 34a of the probe 34 which the calibration robot 30 holds, is moved as predetermined under the control of the CPU 41. Before the calibration, when the X0-Y0 coordinate system is compensated in the coordinate compensating process, a signal outputted by detecting the gold-plated pad 62b for a position index with the inspection probe 34a is inputted into the CPU 41 via an I/F 44b. On the other hand, after the X0-Y0 coordinate system is compensated, the signal outputted by detecting the gold-plated pad 62a for the measurement with the inspection probe 34a is outputted to the oscilloscope 50 in the calibration.

Next, with reference to the flow chart shown in FIGS. 7 and 8, and FIG. 6, the process to be carried out by the CPU 41 in the coordinate compensating process carried out by the calibration device 1 will be explained.

The CPU 41 precisely grasps the center coordinate A of the gold-plated pad 62b for a position index. The X0-Y0 coordinate system which is previously set by the calibration robot 30, is compensated as follows.

The CPU 41 determines an inspection line for causing the inspection probe 34a of the probe 34 to detect the gold-plated pad 62b for a position index (Step S1). The inspection line is determined so as to pass through the gold-plated pad 62b for a position index.

In the first embodiment, two inspection lines are determined from the center coordinate of the gold-plated pad 62b for a position index, which is based on the X0-Y0 coordinate system. The center coordinate is previously stored in the ROM 42 of the control unit 40. That is, as shown in FIG. 5, the inspection line LX is set in the X0 axis direction so as to pass the center coordinate of the gold-plated pad 62b for a position index, which is based on the X0-Y0 coordinate system. Similarly, the inspection line LY is set in the Y0 axis direction so as to pass the center coordinate of the gold-plated pad 62b for a position index, which is based on the X0-Y0 coordinate system. In the first embodiment, the inspection line LX and the inspection line LY are set so as to cross each other perpendicularly.

A coordinate of each inspection position P is set at a predetermined interval “a” along the inspection line LX. The inspection probe 34a of the probe 34 is moved downwardly. The inspection probe 34a is controlled so that the end portion thereof is in contact with the predetermined inspection position P. It is detected whether a portion of the upper surface of the calibration board 60, which is in contact with the inspection probe 34a, has an electric conductivity. The peripheral portion of the gold-plated pad 62b for a position index of the printed board 62 is an insulated portion. Only if the inspection probe 34a is in contact with the inside of the gold-plated pad 62b for a position index, the electric continuity is detected. Thereby, it is detected whether each inspection position P arranged at a predetermined interval “a” along the inspection line LX is within the gold-plated pad 62b for a position index (Step S2).

As shown in FIG. 5, a predetermined interval “a” for setting the inspection position P is set so as to be sufficiently shorter than a diameter R of the gold-plated pad 62b for a position index. Therefore, the gold-plated pad 62b for a position index includes enough inspection positions P to precisely grasp the center coordinate of the gold-plated pad 62b for a position index.

As described above, among the inspection positions P along the inspection line LX, the inspection positions Q included in the gold-plated pad 62b for a position index are grasped. Then, in accordance with the inspection position Q that the gold-plated pad 62b for a position index is detected, the middle coordinate QX is determined (Step S3). In the first embodiment, the middle coordinate QX is determined by using the coordinate which is center between both ends of the gold-plated pad 62b for a position index, which are detected in the inspection positions Q. In FIG. 5, the inspection position Q included in the gold-plated pad 62b for a position index is expressed by a double circle. The inspection position P which is out of the gold-plated pad 62b for a position index, is expressed by a circle.

Like the control (process) for determining the middle coordinate QX along the inspection line LX, the gold-plated pad 62b for a position index is detected in each inspection position P at a predetermined interval “a” along the inspection line LY (Step S4). Then, the middle coordinate QY of the inspection positions Q that the gold-plated pad 62b for a position index is detected is determined (Step S5).

The center coordinate A of the gold-plated pad 62b for a position index is grasped in accordance with the middle coordinate QX and the middle coordinate QY which are determined as described above (Step S6). In the first embodiment, the center coordinate A is determined by an intersection of a line MY which passes through the middle coordinate QX and which is parallel to the inspection line LY, and a line MX which passes through the middle coordinate QY and which is parallel to the inspection line LX perpendicular to the inspection line LY.

In Step S7, it is judged whether the center coordinates A of all of the gold-plated pads 62b for a position index are grasped. When the center coordinates A of all of the gold-plated pads 62b for a position index are not grasped, the process transfers to Step S1 in order to grasp the center coordinate A by carrying out the above process. When the center coordinates A of all of the gold-plated pads 62b for a position index are grasped in Step S7, the process transfers to Step S8. In the first embodiment, the center coordinates A of all of the gold-plated pads 62b for a position index, which are provided in three positions, are grasped.

In Step S8, the X0-Y0 coordinate system is compensated in accordance with the center coordinates A grasped from all of the gold-plated pads 62b for a position index as described above.

As described above, the coordinate compensating process is carried out by the CPU 41.

The above coordinate compensating process may be carried out by precisely grasping the center coordinate of the gold-plated pad 62a for the measurement.

In the calibration of the semiconductor testing apparatus 100, the coordinate of the gold-plated pad 62a for the measurement is precisely compensated in accordance with the compensated X2-Y2coordinate system. The inspection probe 34a of the probe 34 is precisely contacted with the gold-plated pad 62a for the measurement under the control of the CPU 41. Before the calibration, an operator monitors a signal outputted to the oscilloscope 50 via the probe 34 to carry out the calibration. The calibration is carried out for each of 16 printed boards 62 which the calibration board 60 has.

According to the calibration device 1 of the first embodiment, an optional position coordinate which is on the upper surface of the calibration board 60, is compensated by grasping the precise position of the center coordinate A of the gold-plated pad 62b for a position index. Therefore, in the calibration, a coordinate of the gold-plated pad 62a for the measurement, can be precisely compensated.

In order to grasp the center coordinate A of the gold-plated pad 62b for a position index, the probe 34 which is a measurement terminal of the oscilloscope 50 is used. Therefore, a special element for compensating a position of the gold-plated pad 62a for the measurement is not required.

In the first embodiment, when the center coordinate A of one gold-plated pad 62b for a position index is grasped, the CPU 41 sets two inspection lines LX and LY. Further, the calibration board 60 comprises three gold-plated pads 62b for a position index. Therefore, the accuracy of the coordinate compensating process can be improved.

Second Embodiment

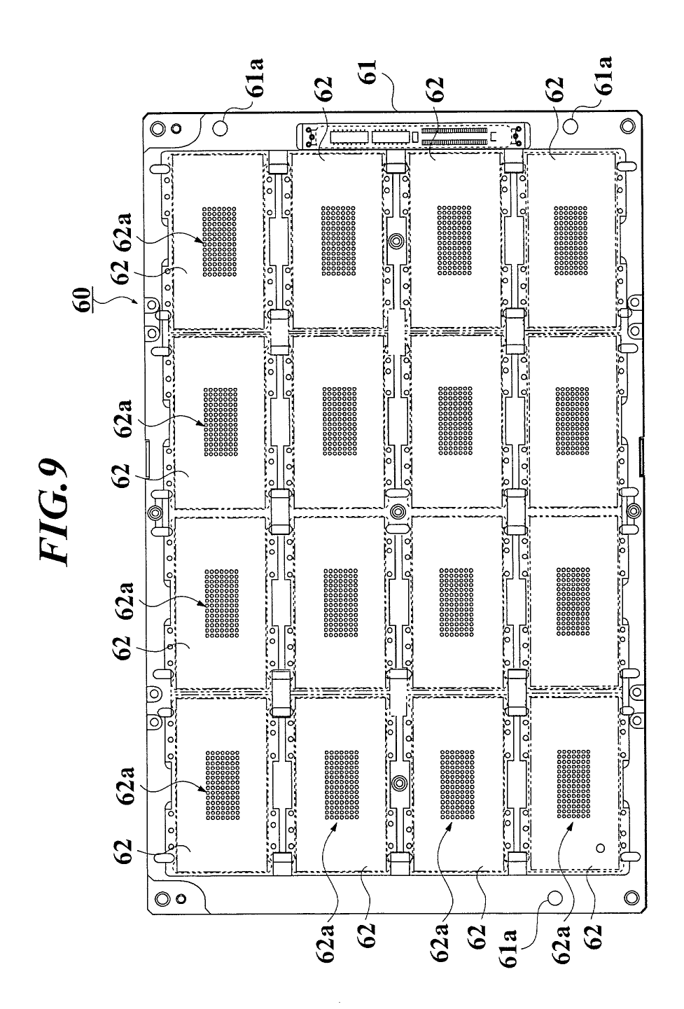

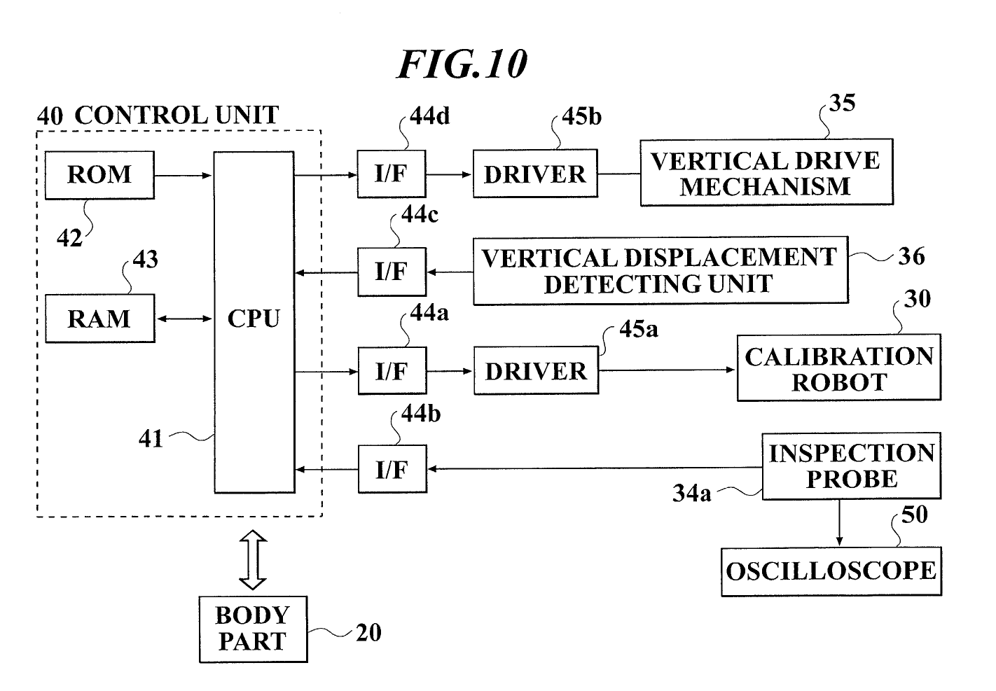

Hereinafter, with reference to FIGS. 9 and 10, the calibration device of the second embodiment will be explained.

The calibration device of the second embodiment is a modified example of the calibration device 1 according to the first embodiment. Therefore, in the following description, some elements which are different from those of the calibration device 1 according to the first embodiment, are mainly explained. The same numeral reference is attached to the same element. The explanation of the same element is omitted.

In the second embodiment, as shown in FIGS. 9 and 10, instead of the gold-plated pads 62b for a position index, a plurality of positioning holes 61a (opening portion) formed from the upper surface of the calibration board 60 are provided in the calibration board 60. In the second embodiment, a positioning pin 34c (inspector) projecting from the lower surface of the support member 33a perpendicularly is provided. The positioning pin 34c is provided besides the inspection probe 34a used in the calibration. Further, a vertical drive mechanism 35 comprising an actuator for moving the positioning pin 34c vertically in the Z-direction shown in FIG. 2, is provided. An end portion of the positioning pin 34c moved vertically by the vertical drive mechanism 35, is monitored about the displacement in the Z-direction by the vertical displacement detecting unit 36.

As shown in the block diagram of FIG. 10, a driver 45b for driving the vertical drive mechanism 35 is connected with the CPU 41 via an I/F 44d. The vertical displacement detecting unit 36 for detecting the displacement of the end portion of the positioning pin 34c, is connected with the CPU 41 via an I/F 44c. In the second embodiment, the coordinate compensating process is carried out by detecting the positioning hole 61a with the CPU 41 in accordance with the displacement of the end portion of the positioning pin 34c in a vertical direction.

As shown in FIG. 9, the positioning holes 61a are provided in three positions. In the second embodiment, the positioning holes 61a are provided on an aluminum base 61 and out of the area that the calibration board 60 is covered with the printed board 62. The position of the positioning hole 61a is not limited to the position shown in the second embodiment. The positioning hole 61a may be provided on the printed board 62.

The concrete construction of the vertical displacement detecting unit 36 is not especially limited if the displacement of the end portion of the positioning pin 34c in a vertical direction can be detected. For example, a sensor, such as a known optical sensor, a magnetic sensor or the like, may be used. Various constructions can be applied to the positioning pin 34c if the positioning hole 61a can be detected by moving the positioning pin 34a in a vertical direction.

That is, in the second embodiment, the inspection section comprises the probe 34, the positioning pin 34c and the vertical displacement detecting unit 36.

As described below, the coordinate compensating process carried out by the calibration device according to the second embodiment, is basically the same as that of the first embodiment except that the positioning hole 61a is detected by the positioning pin 34c.

That is, in the second embodiment, the positioning pin 34c is moved vertically by the vertical drive mechanism 35 in each inspection position P arranged at a predetermined interval “a” along the inspection line set so as to pass the positioning hole 61a. When the positioning pin 34c is moved vertically in the inspection position P out of the positioning hole 61a, the end portion of the positioning pin 34c is in contact with the upper surface of the calibration board 60. On the other hand, in the inspection position Q included in the positioning hole 61a, the end portion of the positioning pin 34c is inserted into positioning hole 61a and is moved below the upper surface of the calibration board 60. That is, in the inspection position Q included in the positioning hole 61a, the end portion of the positioning pin 34c is moved more downwardly as compared with the inspection position P out of the positioning hole 61a.

In the second embodiment, the positioning pin 34c is moved vertically in each inspection position P. When the end portion of the positioning pin 34 is moved to the calibration board 60, the displacement in the Z-direction is monitored by the vertical displacement detecting unit 36. Therefore, it is judged whether each inspection position P is included in the positioning hole 61a.

The calibration device may comprise a structure that the positioning pin 34c is held by the probe 34 so as to be movable vertically and when the positioning pin 34c is moved above the inspection position Q included in the positioning hole 61a, the end portion of the positioning pin 34c is inserted into the positioning hole 61a by self-weight of the positioning pin 34c. In this case, like the above description, the positioning hole 61a can be detected by the displacement in the Z-direction when the end portion of the positioning pin 34c is moved to the calibration board 60.

According to the calibration device of the second embodiment, the same effect as the calibration device 1 according to the first embodiment can be obtained. Even though space for providing the gold-plated pad 62b for a position index on the upper surface of the printed board 62 is not secured enough, the coordinate compensating process can be carried out by using the positioning hole 61a provided on the aluminum base 61.

The present invention is not limited to the above embodiments.

For example, in the coordinate compensating process carried out by the calibration device 1 according to the first embodiment, a concrete process for determining the center coordinate A of the gold-plated pad 62b for a position index is not limited to the process described in the first embodiment. Various statistical processes may be carried out when the center coordinate A is determined. A concrete process for compensating the X0-Y0 coordinate system in accordance with the determined center coordinate A is not limited. Various statistical processes may be applied.

Needless to say, any other concrete detail constructions or processes may be suitably changed.

According to the present invention, because an optional coordinate which is on the upper surface of the calibration board is compensated, the coordinate of the measurement position of the calibration can be precisely grasped. Therefore, the probe can be precisely introduced in accordance with the compensated coordinate.

Further, it can be easily grasped whether each position arranged at predetermined intervals along the inspection line is included in the inspection reference portion.

Because the center coordinate of the inspection reference portion is grasped more precisely, the accuracy of the compensation of an optional position coordinate of the upper surface of the calibration board can be improved.

By detecting the electric continuity between the inspection reference portion having an electric conductivity and the inspection section, the inspection reference portion can be suitably detected.

Because the coordinate of the measurement position is compensated by using an ordinary structure, the calibration device can have a simple structure and the manufacturing cost thereof can be reduced.

When the gold-plated pad is detected along the inspection line passing through the gold-plated pad which is the inspection reference portion, it is clear whether there is an electric continuity within or out of the gold-plated pad. Therefore, the gold-plated pad can be suitably detected.

By monitoring the displacement of the end portion of the inspection section in the vertical direction with the vertical displacement detecting unit, the area for detecting the inspection reference portion along the inspection line can be suitably grasped.

The entire disclosure of Japanese Patent Application No. Tokugan 2000-299789 filed on Sept. 29, 2000 including specification, claims drawings and summary are incorporated herein by reference in its entirety.

What is claimed is:

1. A calibration device for a semiconductor testing apparatus, comprising:
an inspection section comprising an inspector for detecting an inspection reference portion provided on a calibration board mounted on the semiconductor testing apparatus;
a movement section for moving the inspector to an optional position of an upper surface of the calibration board, and for moving the inspector vertically in the optional position of the upper surface of the calibration board; and
a control unit for setting an inspection line passing through the inspection reference portion, for controlling the inspector so as to move the inspector along the set inspection line to detect the inspection reference portion, for determining a center coordinate of the inspection reference portion in accordance with a middle coordinate of a range that the inspection reference portion is detected along the set inspection line, and for compensating a coordinate of a measurement position of the calibration board in accordance with the determined center coordinate in order to precisely contact a probe with the measurement position.

2. The calibration device as claimed in claim 1, wherein the inspector is controlled to move the inspector to each position which is arranged at predetermined intervals along the inspection line.

3. The calibration device as claimed in claim 1, wherein the control unit sets a plurality of inspection lines to the inspection reference portion.

4. The calibration device as claimed in claim 1, wherein the inspection reference portion has an electric conductivity; and
the control unit detects the inspection reference portion by detecting an electric continuity between the inspector and the inspection reference portion.

5. The calibration device as claimed in claim 4, wherein the inspector is the probe for detecting a signal to calibrate the semiconductor testing apparatus; and
the movement section is a calibration robot for contacting the probe with the measurement position of the calibration board when the semiconductor testing apparatus is calibrated.

6. The calibration device as claimed in claim 4, wherein the calibration board comprises a printed board; and
the inspection reference portion is a gold-plated pad which is previously provided on the printed board.

7. The calibration device as claimed in claim 1, wherein the inspection reference portion is an opening portion formed on the upper surface of the calibration board mounted on the semiconductor testing apparatus;
the inspection section comprises a vertical displacement detecting unit for detecting a displacement of an end portion of the inspector in upper and lower direction; and
the control unit sets the inspection line passing through the opening portion, controls the inspector so as to move the inspector along the set inspection line, and detects the opening portion in accordance with the detected displacement of the end portion of the inspector in the upper and lower direction.

8. A calibration method for calibrating a semiconductor testing apparatus, comprising:
setting an inspection line passing through an inspection reference portion provided on a calibration board mounted on the semiconductor testing apparatus;
moving an inspector for detecting the inspection reference portion along the set inspection line in order to detect the inspection reference portion;
determining a center coordinate of the inspection reference portion in accordance with a middle coordinate of a range that the inspection reference portion is detected along the set inspection line; and
compensating a coordinate of a measurement position of the calibration board in accordance with the determined center coordinate in order to precisely contact a probe with the measurement position.

9. The calibration method as claimed in claim 8, wherein the inspector is moved to each position arranged at predetermined intervals along the inspection line.

10. The calibration method as claimed in claim 8, wherein a plurality of inspection lines are set to the inspection reference portion.

11. A semiconductor testing apparatus comprising:
a calibration device for the semiconductor testing apparatus, the calibration device comprising:
an inspection section comprising an inspector for detecting an inspection reference portion provided on a calibration board mounted on the semiconductor testing apparatus;
a movement section for moving the inspector to an optional position of an upper surface of the calibration board, and for moving the inspector vertically in the optional position of the upper surface of the calibration board; and
a control unit for setting an inspection line passing through the inspection reference portion, for controlling the inspector so as to move the inspector along the set inspection line to detect the inspection reference portion, for determining a center coordinate of the inspection reference portion in accordance with a middle coordinate of a range that the inspection reference portion is detected along the set inspection line, and for compensating a coordinate of a measurement position of the calibration board in accordance with the determined center coordinate in order to precisely contact a probe with the measurement position.

12. The semiconductor testing apparatus as claimed in claim 11, wherein the inspector is controlled to move the inspector to each position which is arranged at predetermined intervals along the inspection line.

13. The semiconductor testing apparatus as claimed in claim 11, wherein the control unit sets a plurality of inspection lines to the inspection reference portion.

14. The semiconductor testing apparatus as claimed in claim 11, wherein the inspection reference portion has an electric conductivity; and
the control unit detects the inspection reference portion by detecting an electric continuity between the inspector and the inspection reference portion.

15. The semiconductor testing apparatus as claimed in claim 14, wherein the inspector is the probe for detecting a signal to calibrate the semiconductor testing apparatus; and
the movement section is a calibration robot for contacting the probe with the measurement position of the calibration board when the semiconductor testing apparatus is calibrated.

16. The semiconductor testing apparatus as claimed in claim 14, wherein the calibration board comprises a printed board; and
the inspection reference portion is a gold-plated pad which is previously provided on the printed board.

17. The semiconductor testing apparatus as claimed in claim 11, wherein the inspection reference portion is an opening portion formed on the upper surface of the calibration board mounted on the semiconductor testing apparatus;
the inspection section comprises a vertical displacement detecting unit for detecting a displacement of an end portion of the inspector in upper and lower direction; and
the control unit sets the inspection line passing through the opening portion, controls the inspector so as to move the inspector along the set inspection line, and detects the opening portion in accordance with the detected displacement of the end portion of the inspector in the upper and lower direction.
